(19) United States
(12) Patent Application Publication
(10) Pub. No.: US 2009/0129363 A1
(43) Pub. Date: May 21, 2009

(54) Automatic Volume Restoration in a Distributed Communication System

(76) Inventors: Steven R. Lindsey, Lehi, UT (US); Richard C. Lindsey, Payson, UT (US); Craig B. DeVries, Bountiful, UT (US)

Correspondence Address: MORRISS OBRYANT COMPAGNI, P.C., 734 EAST 200 SOUTH, SALT LAKE CITY, UT, 84102, US

(21) Appl. No.: 11/944,035

(22) Filed: Nov. 21, 2007

(51) Int. Cl. H04J 3/00; H03G 3/00

(52) U.S. Cl. 370/345; 381/104

(57) ABSTRACT

A distributed home communications system automatically restores settings, such as volume levels, on each communication node when initiating a connection associated with various communication types in paging, public address, two-way radio, intercoms, music distribution systems, and the like.

### TECHNICAL FIELD

Embodiments of the present invention generally relate to communication and media distribution systems; and more particularly to systems with automatic volume control including restoration of output to defined levels.

### BACKGROUND

Audio communication and/or distribution systems, such as a home intercom multimedia system, traditionally provide manual volume controls to a local listening device via potentiometers or digital attenuators to allow users a way to adjust the level (or loudness) of audio signals presented to an output device, such as a loudspeaker or headphone, associated with a particular location. Typically, users can access these manual volume controls via knobs on the listening devices through which they listen to a broadcast or transmission of audio information.

Although manually adjusting the volume locally at the listening device provides a certain level of convenience to the local user, when the volume is inadvertently set too low or too high by the local user the effectiveness of the entire communication and/or distribution system may be compromised. In these cases, many of the manually adjusted individual communication devices of the system are ineffective. If set too low, manually adjusted communications systems may appear dysfunctional; if set too high, they may cause irritation and/or damage to the unit.

For example, a police officer in a patrol car might turn the volume control down on his two-way radio and then forget to turn it up again. The next time the dispatcher tries to make contact the officer may not hear the incoming call. The same thing is true for an intercom system in a home or office. A child in a bedroom, for instance, may turn the volume down on the bedroom intercom station. When a parent tries to call, the child may not hear the communication, and the parent may mistakenly believe that the message was received, and therefore expect the child to complete the requested task (e.g., answer the phone or come to dinner). If the intercom station in the child's room were to automatically change to the preset volume desired for a direct two-way intercom type connection, then the parent would have confidence in being heard in the child's room regardless of the level the child previously changed the volume to.

Another problem with manual volume controls is the potential for feedback or even ear damage caused by the output level being set too high. Not only can this feedback damage the system, but it also disrupts communication. A person listening on a headset is vulnerable to ear damage if the sound is set too loud when a new connection is initiated. There is also a potential for equipment damage due to excessive volume. For example, an intercom system with a whole-home paging option will most certainly start to introduce a feedback signal into the transmission, and thus produce a squeal if the volume of even one of the room's stations is too high when the whole-house page is started. This undesirable outcome may prevent proper communication from taking place. If the volume level of each room were to automatically change to the preset desired level for a whole-home paging type connection when the page begins, then the homeowner is guaranteed to never have a feedback experience with the intercom system, and thus always be ensured of effective communication.

### BRIEF DESCRIPTION OF THE DRAWINGS

To further clarify the advantages and features of the present invention, a more particular description of the invention will be rendered by reference to specific embodiments thereof that are illustrated in the appended drawings. It will be appreciated that these drawings depict only typical embodiments of the invention and are therefore not to be considered limiting of the scope of the invention. The invention will be described and explained with additional specificity and detail through the use of the accompanying drawings.

FIG. 1 illustrates a diagram of a portion of a distributed home communication system in accordance with various embodiments of the present invention;

FIG. 2 illustrates a diagram of a portion of a distributed communication system with a plurality of communication nodes in accordance with various embodiments of the present invention;

FIG. 3 illustrates a block diagram of a portion of a communication node as presented in FIG. 2 in further detail, in accordance with various embodiments of the present invention;

FIG. 4 illustrates a flow diagram view of a method of operation for automatic volume restoration in accordance with various embodiments of the present invention;

FIG. 5 illustrates a flow diagram view of a method of operation for home communication node setting restoration in accordance with various embodiments of the present invention;

FIG. 6 illustrates a flow diagram view of a method of operation for user configuration in accordance with various embodiments of the present invention; and

FIG. 7 illustrates a flow diagram view of a method of operation for a home communication node using interrupts in accordance with various embodiments of the present invention.

### DETAILED DESCRIPTION

Briefly stated, a need exists in the home communications/intercom art for a method and system for automatically restoring volume levels to pre-defined factory or user-defined settings when initiating communications in paging, public address, two-way radio, intercoms, music distribution systems and the like.

In the following detailed description, reference is made to the accompanying drawings wherein like numerals designate like parts throughout, and in which specific embodiments in which the invention may be practiced are illustrated. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

Throughout the specification and claims, the following terms take at least the meanings explicitly associated herein, unless the context clearly dictates otherwise. The meanings identified below are not intended to limit the terms, but merely provide illustrative examples for use of the terms. The meaning of a, an, and the may include reference to both the singular and the plural. Reference in the specification to “one embodiment” or “an embodiment” means that a particular feature, structure, or characteristic described in connection with the embodiment is included in at least one embodiment of the invention. The meaning of in may include in and on. The appearances of the phrases “in one embodiment” or “in an embodiment” in various places in the specification mayor may not refer to the same embodiment. The term connected may mean a direct electrical, electromagnetic, mechanical, logical, or other connection between the items connected, without any electrical, mechanical, logical or other intermediary therebetween. The term coupled can mean a direct connection between items, an indirect connection through one or more intermediaries, or communication between items in a manner that may not constitute a connection. The term circuit or circuitry as used in any embodiment described herein, can mean a single component or a plurality of components, active and/or passive, discrete or integrated, that are coupled together to provide a desired function and may include, for example, singly or in any combination, hard-wired circuitry, programmable circuitry, state machine circuitry, and/or firmware that stores instructions executed by programmable circuitry. The term signal can mean at least one current, voltage, charge, data, or other such identifiable quantity.

In an effort to clarify comparative phrases used in the specification and the claims of this disclosure, please note that the following phrases take at least the meanings indicated and associated herein, unless the context clearly dictates otherwise. The phrase “A/B” means “A or B”. The phrase “A and/or B” means “(A), (B), or (A and B)”. The phrase “at least one of A, B and C” means “(A), (B), (C), (A and B), (A and C), (B and C) or (A, B and C)”.

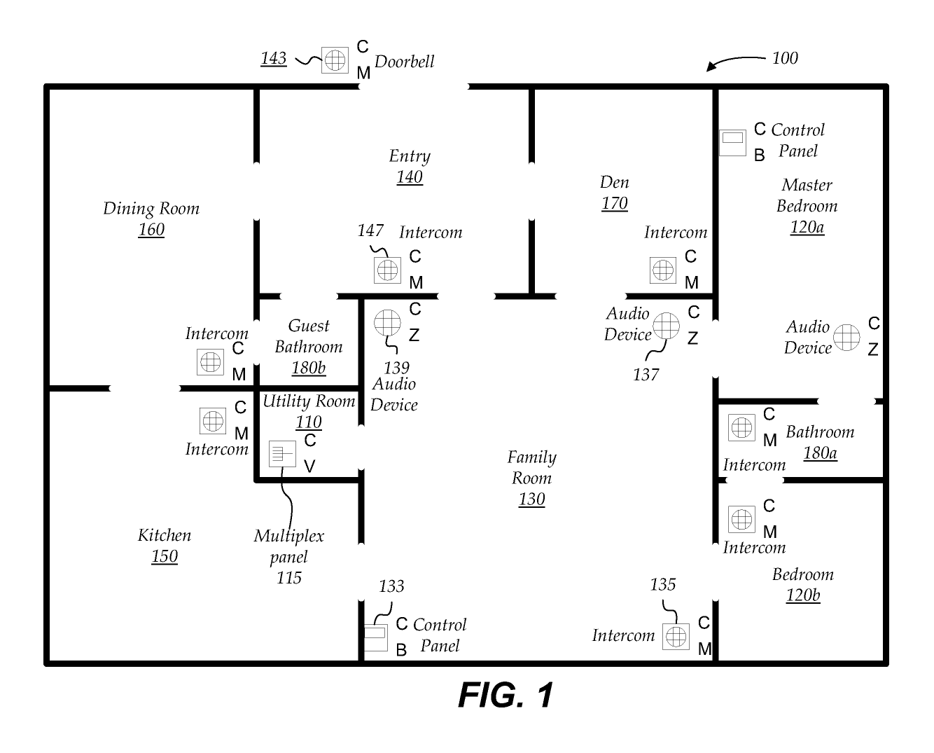

Referring now to FIG. 1, a diagram of a portion of a distributed home communication system, shown generally at arrow 100 is shown in accordance with various embodiments of the present invention. The distributed home communication system 100 includes both a variety of operating environments and a variety of network devices. Operating environments within a given home communication system 100 may include, but are not limited to, a utility room 110, a bedroom 120, a family room 130, an entry room area 140, a kitchen 150, a dining room 160, a home office or den 170, and even bathrooms 180. Each operating environment (i.e., 110-180) may present a unique set of criteria and needs with respect to configuring the communication node or other network device within the operating environment. The communication system 100 may also include multiple rooms of a given operating environment (e.g., master bedroom 120a and bedroom 120b or bathroom 180a and guest bathroom 180b). In various embodiments, the communication system 100 does not include every operating environment (e.g., a home system may not have a Den 170). Moreover, it should also be understood that other portions and embodiments of the distributed home communication system 100 may include other operating environments not presently shown in FIG. 1, but within the scope of the invention, such as a garage, a backyard patio, a spa, a sports court, a pool, and the like.

Network devices within a given home communication system 100 may include, but not be limited to, multiplex media panels 115, as shown in utility room 110, two-way radios (not shown), paging devices (not shown), intercom stations (see e.g., 135, 147), music distribution devices (see e.g., audio devices 137 and 139), digital doorbells 143, control panels 133, public address systems (not shown), and other similar devices that may have either a factory default or user-defined preset volume levels, whenever a new communication or broadcast session is initiated.

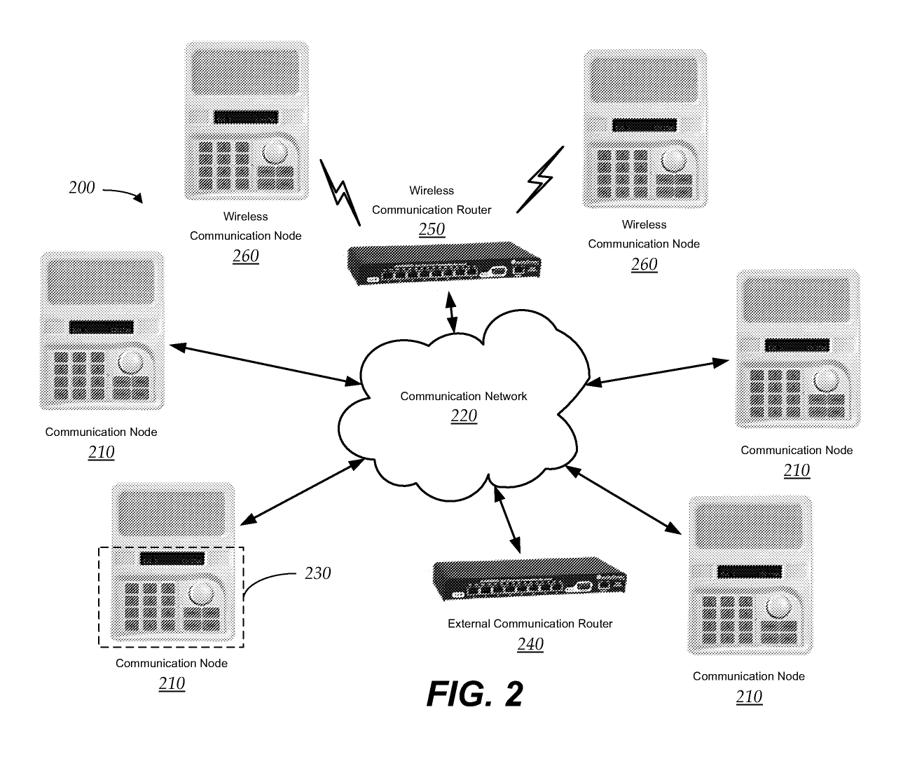

Referring now to FIG. 2, a diagram of a portion of a distributed communication system 200 with a plurality of communication nodes 210 is shown in accordance with various embodiments of the present invention. In one embodiment, the distributed communication system 200 includes a plurality of communication nodes 210 coupled to a communication network 220. The communication network 220 may comprise a local area network (LAN) and/or a wide area network (WAN). In one embodiment, an external communication router 240 couples the communication network 220 to an interconnected system of networks (not shown), such as the public Internet. Various embodiments of the distributed communication system 200 include a wireless communication router 250 to couple wireless communication nodes 260 to each other and to the communication nodes 210 on the communication network 220. In one embodiment, each network connection may be wired or wireless (250) or some combination thereof.

Each communication node 210 has a user interface 230, which may include a keypad, rotary encoder, pushbutton device, and/or touch screen device, and may also include a screen or indicator (e.g., LCD, LED) that either displays the current setting or provides feedback to the end-user of the status of the setting. In addition to an intercom station, the communication node 210 may also be configured as a listening device, a master controlling device, and/or a remotely connected device such as a computer or remote control. In one embodiment, when a new broadcast or communication type is initiated from a transmitting communication node 210, a processing and/or control device at the listening communication node 210 determines the type of communication that has been requested and looks up the appropriate volume level from the memory, then configures the receiving device to update its volume level. Alternatively, in one embodiment, the various communication and volume levels for each node in the distributed communication system 200 may be stored remotely at a master controlling device or server.

In one embodiment, the volume level for a specific connection type across the communication network 220 may be altered at each communication node 210 using the user interface. In one configuration these alterations to change the default volume may be made after a specific connection type has been initiated, the user may override the volume by simply changing the volume using the standard method appropriate for the device. The volume will remain at the level adjusted by the user for the duration of the connection. However, in one embodiment the default volume will be used again when the connection ends and a new connection is established.

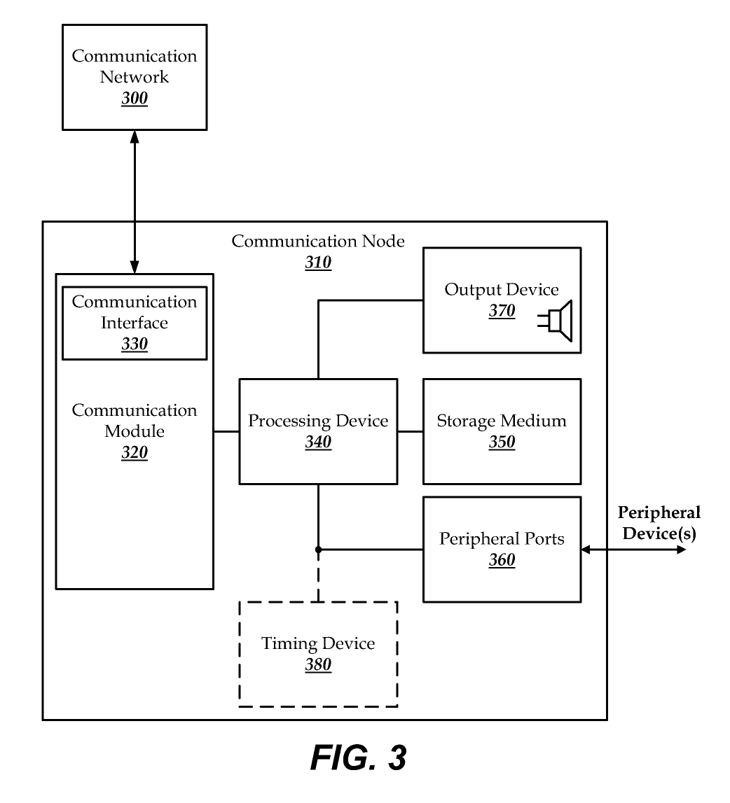

Referring now to FIG. 3, a block diagram of a portion of a communication node 310 as presented in FIG. 2 (e.g., communication node 210 and wireless communication node 260) is shown in further detail, in accordance with various embodiments of the present invention. In the illustrated embodiment, the communication node 310 is coupled to a communication network 300 via a communication module 320 with a communication interface 330. Communication node 310 further includes a processing device 340 connected to the communication module 320, storage medium 350, output device 370, and peripheral ports 360. The illustrated communication node 310 also includes an output device 370 having multiple volume settings that may be automatically adapted in accordance with various connection types. Various connection types may be used between communication nodes 310 and may include, but are not limited to, an intercom connection type, a music connection type, a door-chime connection type, a video connection type, a data connection type, and a multimedia connection type.

In one embodiment, the processing device 340 includes at least one processor. As such, the term “processor”, as used herein, should be interpreted to mean an individual processor, firmware logic, reconfigurable logic (e.g., field programmable gate array (FPGA) or erasable programmable read only memory (EPROM)), a hardware description language logic configuration, a state machine, an application-specific integrated circuit (ASIC), a processing core co-disposed in an integrated circuit package with at least one other processing core and/or component, or combinations thereof. The processing device 340 may include a microprocessor, a microcontroller, an FPGA, or an ASIC, with internal and/or external memory writing capability that may be configured and/or used to save the preferred communication settings as entered by the end-user. In one embodiment, processing device 340 may be configured to send control signals to a digitally controlled attenuator or a stepping motor connected to a potentiometer to adjust the volume to the preset level when a specific communication or broadcast type is initiated.

Various embodiments of the communication module 320 provide a method of using either factory-set or user-defined volume levels for various connection types, which may be stored locally in the storage medium 350 or received from a remote storage location via the communication network 300. Memory and/or storage on the storage medium 350 includes any mechanism that stores and/or transmits information in a form readable by a machine (e.g., a computer). For example, a storage medium includes read only memory (ROM), random access memory (RAM), EPROM, magnetic disk storage media, optical storage media, flash memory devices, electrical, optical, acoustical or other form of propagated signals (e.g., carrier waves, infrared signals, digital signals), and the like. In addition to communication settings, the storage medium 350 may also be used to store digitized audio signals for use by the output device 370. Typically, digitized audio signals are stored in a compressed format such as a lossy compression (e.g., MP3, MP4, etc.) or a lossless compression format (e.g., Direct Stream Transfer (DST), Free Lossless Audio Codec (FLAC), Shorten (SHN), Meridian Lossless Packing (MLP), Windows Media (WMA) Lossless, Apple Lossless Audio Codec (ALAC), RealAudio Lossless, True Audio Lossless (TTA), WavPack Lossless, Dolby True HD, DTS-HD MasterAudio, etc.). In one embodiment, the digitized signals may be received and/or transmitted across the communication network 300 via the peripheral ports 360.

In one embodiment, the communication node 310 provides the end-user with a communication interface 330 to customize the default volume levels to play audio signals according to a user's preferences. In any case, a memory device such as the storage medium 350 may be used to store the volume settings for each listening device and for each communication type. In various embodiments where the end-user can customize their preferred volume levels, a re-writable memory storage device may be employed as well as a memory storage device that tolerates power outages.

In various embodiments, the communication node 310 includes peripheral ports 360 that allow the communication node 310 to interface with other audio/visual sources via peripheral devices. These peripheral devices may include suitable mono or stereo audio components such as, for example, a Digital Video Disc (DVD) player, a compact disc (CD) player, a mini-disc (MD) player, a digital audio tape (DAT) player, an MP3 player, a cassette tape player, a digital compact cassette (DCC) player, and variations thereof or any other suitable audio source. The attached peripheral devices may also be any suitable audio/visual source such as, for example, a television receiver, a cable television receiver, a satellite video receiver, a digital video camera, DVD player, or any other suitable audio/video source. The communication node 310 may also be interfaced via the peripheral device to one or more audio speakers (see e.g., audio devices 137 and 139 in FIG. 1). The audio that may be delivered over the communication network 300 may include any low, middle and high-end digital audio standards including Dolby™, Digital™, DTS™, and other home theater surround sound technologies. In addition to the previously described examples, a digital pre-processor can be applied to digital information from the various sources. In one example, digital data is retrieved from a storage medium 350, such as an internal flash memory or a hard disk drive in a digital media player device.

In one embodiment, the communication node 310 optionally includes a timing device 380 shown in dotted lines. The timing device 380 may include a clock (not shown) to help identify various operational time periods. For example, if a doorbell signal is sent after a designated time period, such as 9 PM, the communication node 310 located in a baby's bedroom may be set to ignore the signal, transmit a visual signal, and/or transmit at a different audio level than during the day. In another example, the communication node 310 may attempt to avoid door bell pranksters after a designated time period on the optional timing device 380, such as 1 AM, by requiring multiple rings before producing the requested output signal. In one embodiment, the optional timing device 380 may also be accessed by the processing device 340 to coordinate transmission of signals. For example, an alarm might be set to wake everyone up at a designated time. Alternatively, a dinner bell might be coordinated according to the settings of the timing device 380.

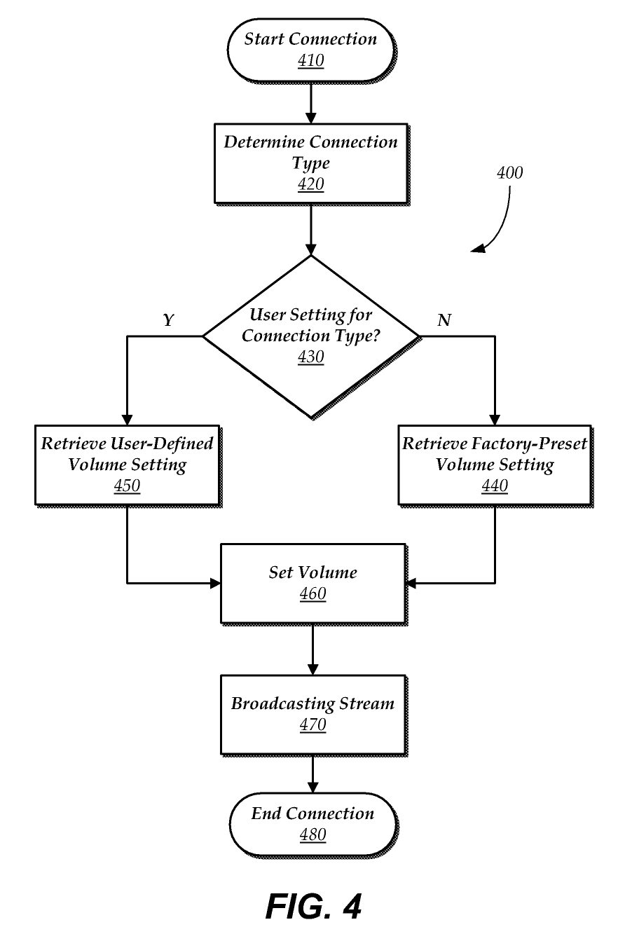

Turning now to FIGS. 4-7, methods in accordance with various embodiments are described in terms of firmware (e.g., firmware that is used by a processor, such as a micro-processor, a micro-controller, an ASIC, and/or a digital signal processor (DSP)), software, and/or hardware with reference to flow diagrams. Describing a method by reference to a flow diagram enables one skilled in the art to develop programs, including instructions, to carry out the methods on suitably configured electronic communication devices. In various embodiments, portions of the operations to be performed by a communication device may constitute circuits, general purpose processors (e.g., micro-processors, micro-controllers, or digital signal processors), special purpose processors (e.g., FPGAs or ASICs), state machines, hardware arrays, reconfigurable hardware, and/or software made up of executable instructions. The executable instructions may be embodied in firmware logic, reconfigurable logic, a hardware description language, a state machine, an ASIC, or combinations thereof.

With respect to various embodiments using a software implementation (e.g., a hardware simulator), at least one of the processors of a suitably configured electronic communication device executes the instructions from a storage medium. The computer-executable instructions may be written in a computer programming language or executable code. If written in a programming language conforming to a recognized standard, such instructions may be executed on a variety of hardware platforms and may interface with a variety of operating systems. Although the various embodiments are not described with reference to any particular programming language, it will be appreciated that a variety of programming languages may be used to implement the teachings of the embodiments as described herein. Furthermore, it is common in the art to speak of software in one form or another (e.g., program, procedure, process, application, etc.) as taking an action or causing a result. Such expressions are merely a shorthand way of saying that execution of the software by a device causes the processor of the computer to perform an action or a produce a result.

Referring now to FIG. 4, a flow diagram view of a portion of a process 400 of operation for automatic volume control in a communication module of a distributed communication system is shown in accordance with various embodiments. Collectively, the connection type determination, setting selection, volume restoration, and subsequent transmission operations may be referred to as the automatic volume restoration process 400. The process 400 begins to initiate a connection in block 410. The initiation of the connection 410 may be a result of a request received or generated by a communication node. In one embodiment, the request to start a connection of a transmission stream 410 is generated by a first communication node and the process 400 subsequently retrieves the requested transmission stream from a storage medium coupled to a second communication node. Alternatively, the transmission may be stored by the same communication node that originates the connection request.

The process 400 determines the connection type in block 420. As previously stated, various connection types 420 may be used between communication nodes (including but not limited to an intercom connection type, a music connection type, a door-chime connection type, a video connection type, a data connection type, and a multimedia connection type). Each connection type may be selectively transmitted to specific communication nodes and/or broadcast to multiple communication nodes (e.g., the entire network).

Briefly stated, an intercom connection type, in accordance with various embodiments of the present invention, represents a communication link to couple the communication node and at least one other device in the distributed home communication system. The other devices may include doorbell stations, intercom stations, audio stations, control panel stations, multiplex stations, external weatherproof stations, wireless stations, and other system extensions.

A music connection type, in accordance with various embodiments of the present invention, may represent a digitized audio signal or digital music stream being sent or requested by the communication node. The music connection type may include a variety of digitized audio signals which may be stored in an analog signal format or a compressed digital format, such as a lossy compression or a lossless compression format as previously described. Moreover, a variety of devices and/or peripheral devices may receive or transmit the music to the communication node. As previously indicated suitable music source devices may include mono or stereo audio components such as, for example, a Digital Video Disc (DVD), a compact disc (CD) player, a mini-disc (MD) player, a digital audio tape (DAT) player, an MP3 player, a cassette tape player, a digital compact cassette (DCC) player, and variations thereof or any other suitable audio source. Suitable music output devices may include any audio output devices coupled with a particular communication node, such as a loudspeaker or headphone. The loudspeakers may include an audio system configured to receive any low, middle and high-end digital audio standards including Dolby™, Digital™, DTS™, and other home theater surround sound technologies.

A door-chime connection type, in accordance with various embodiments of the present invention, represents a signal being sent to notify the communication node from an input station, such as the doorbell station 143 in FIG. 1. Typically, the door-chime connection type may briefly interrupt or replace any ongoing audio stream at the communication node, such as a music connection type. Alternatively, the door-chime connection type may be delayed until after certain connection types are finished, such as an intercom connection type. Other variations of the door-chime connection type provide a temporary override of other connection types. The door-chime connection type may or may not include the actual audio signal in the transmitted signal. In one embodiment, each communication node may be individually configured to store and/or transmit a unique door chime. In one embodiment, a timing device on the communication node regulates the type of response generated upon receipt of a door-chime connection type. For example, certain communication nodes may set the volume level to inaudible levels during certain times of the day/night. Other communication nodes may not respond at all unless multiple door-chime connection type requests are transmitted within a designated time period.

A video connection type, in accordance with various embodiments of the present invention, represents a digitized video signal or digital video stream being sent or requested by the communication node. The video connection type may include a variety of digitized pictures and/or video signals which may be stored in an analog signal format or a compressed digital signal format. Moreover, a variety of devices and/or peripheral devices may receive or transmit the video to the communication node. Suitable video source devices may include previously mentioned video components such as, for example, a television receiver, a cable television receiver, a satellite video receiver, a digital video camera, DVD player, a video CD (VCD) player, a mini-disc (MD) player, an MP4 player, and variations thereof or any other suitable audio/video source.

A multimedia connection type, in accordance with various embodiments of the present invention, may represent a digitized multimedia signal or media stream being sent or requested by the communication node. In one embodiment, the multimedia connection type represents a combination of audio and video connection types.

A data connection type, in accordance with various embodiments of the present invention, may represent a data stream or a sequence of digitally encoded coherent data signals used to transmit or receive information at the communication node. In one embodiment, the data connection type may include packets of data, unlike the music connection type and video connection type. Typically the data connection type may run in the background of the other connection types

Other connection types may be used within the distributed home communication system to facilitate operations and to provide various features. Such connection types may include alarm connection types to alert communication nodes, system connection types to identify system features, and query connection types to request operational parameters of communication nodes and attached peripherals. Each connection type may be associated with a variety of communication attributes, such as a predefined volume level setting and/or priority level setting.

Upon determining the connection type in block 420, the process 400 determines whether user settings have been enabled for the connection type discovered in query block 430. If available, the process 400 retrieves user-defined settings in block 450. In one embodiment, the user-defined settings will be stored locally in the storage medium of the communication node. Another embodiment receives the settings from a remote device transmitting to the communication node. If user-defined settings are not available, or are not complete, the process 400 may retrieve the factory-preset settings in block 440.

The process 400 applies the retrieved settings to the communication node in block 460. In one embodiment, retrieved settings include the local volume control settings. The local volume settings may include user-defined volume settings assigned in accordance with environmental characteristics of the communication node to broadcast the transmission. For example, if the communication node is in a family room, the volume associated with a door-chime connection type may be increased. In a similar fashion, volume settings in the baby's room for a door-chime connection type may be drastically reduced after a designated bedtime. Typically, the factory default setting will establish a loud audible volume level for a given connection type.

Once the communication node has set the applicable volume settings, the process 400 broadcasts the transmission stream in block 470 according to the retrieved volume control configuration information for the received connection type. Upon completion of the stream, the process 400 terminates the connection in block 480.

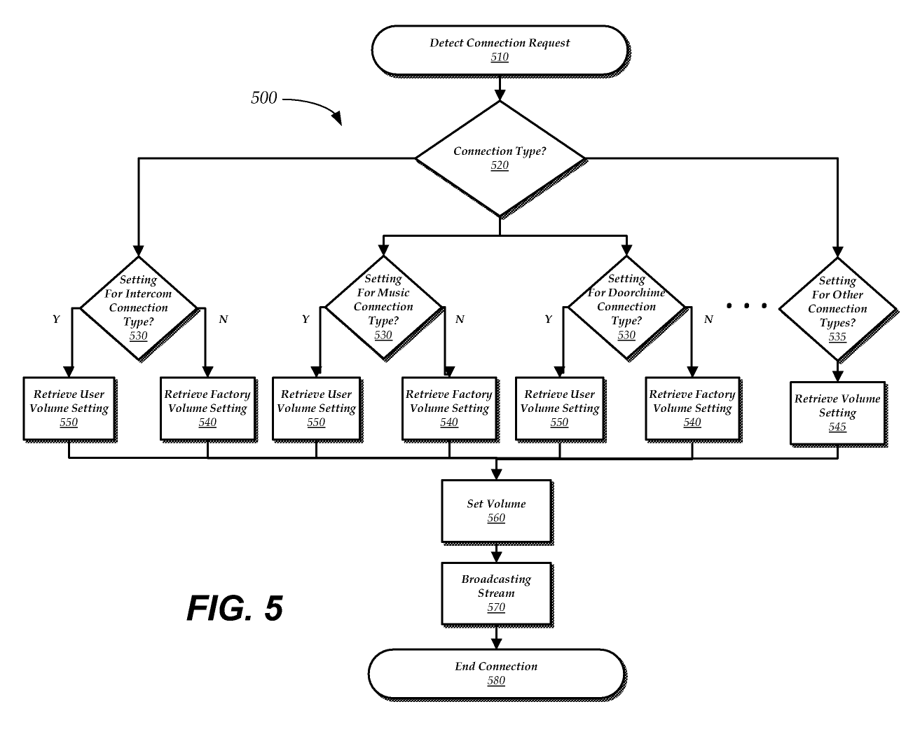

Referring now to FIG. 5, a flow diagram view of a portion of a process 500 of operation for automatic volume setting in a distributed home communication system as presented in FIG. 1 is shown in accordance with various embodiments. Collectively, the connection detection, connection type determination, volume setting source selection, and volume retrieval/restoration operations may be referred to as the home communication node volume setting process 500. The process 500 operating on a communication node, such as those depicted in FIGS. 1-3, detects a connection request in block 510. The requested connection may be a result of a request received or generated by the communication node. The process 500 determines the connection type in block 520. As previously discussed, a variety of connection types may be used between communication nodes. The connection types illustrated in FIG. 5 are an intercom connection type, a music connection type, a door-chime connection type, and other connection types. The other connection types may include, but are not limited to, a video connection type, a data connection type, an alarm connection type, a system connection type, and a query connection type, according to the features of the individual device and the associated distributed communication network.

Once the connection type has been determined by the processing device of the communication node, the process 500 may either determine the communication settings for the specific connection type in query blocks 530 or determine a default communication setting in query block 535. Each query block 530 enables the process 500 to determine whether a customized user volume setting is to be retrieved in block 550 or a factory default volume setting is to be retrieved in block 540. As illustrated, the process defaults to the factory volume setting unless a user setting has been made. Alternative configurations may default to a master volume setting for the system or other equivalent system-wide volume setting for the communication nodes.

Upon retrieving the volume setting, the process 500 sets the volume for the communication node in block 560. The process begins the stream associated with the respective connection type in block 570. As previously indicated, the source of the stream may be received from an external device across the communication network or a storage medium coupled to the communication node or attached peripheral device. Upon completion of the stream, the process 500 terminates the connection in block 580.

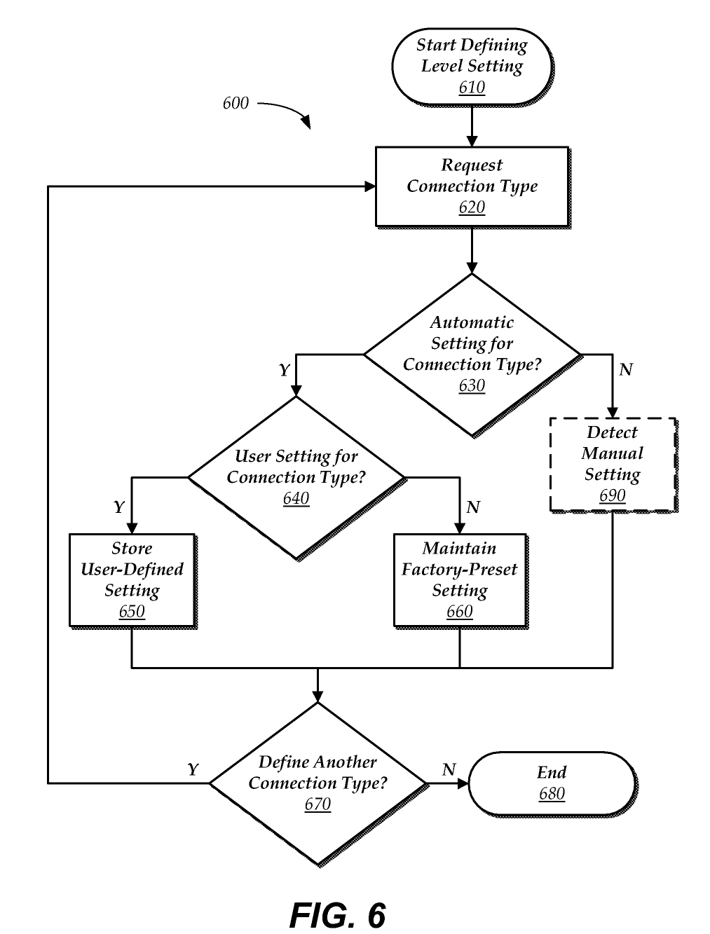

Referring now to FIG. 6, a flow diagram view of a portion of a process 600 of operation for automatic volume restoration is shown in accordance with various embodiments. Collectively, the connection type request, automatic setting application, storage, and maintenance operations may be referred to as the user configuration process 600. The process 600 operating on a communication node, such as those depicted in FIGS. 1-3, begins defining level settings associated with various connection types in block 610. The process 600 requests a connection type in block 620. A variety of different connection types as previously described may be selected. The settings associated with the various connection types may be retrieved from a storage medium coupled to the communication node such that the setting information may be stored locally and/or remotely.

In query block 630, the process 600 determines whether the communication node allows an automatic setting to be applied to the selected connection type. If automatic settings are not available, the process 600 may optionally detect any manual settings in block 690 (shown in dotted line) that have been established for the connection type before continuing to query block 670. If automatic settings are available for the selected connection type, the process 600 determines whether to use a customized user-defined setting in block 650 or to maintain a factory preset setting in query block 660. If a user-defined setting is selected, the process 600 stores the collected setting information in block 650. The setting information may include volume settings, signal priority, signal duration, and other signal characteristics. The setting information may be collected from a user using a user interface, as previously described, which may in one embodiment include a keypad, rotary encoder, pushbutton device, and/or touch screen device.

In query block 670, the process 600 determines whether additional connection types may be defined. If additional connection types remain to be set the process 600 returns to block 620 and requests the next connection type. Alternatively, the process 600 terminates the connection type initialization in block 680.

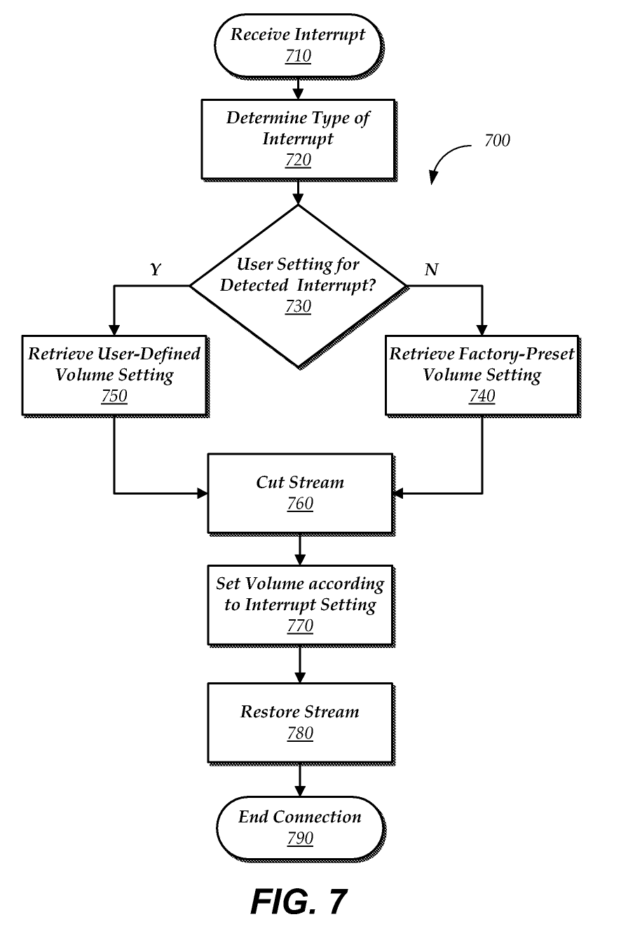

Referring now to FIG. 7, a flow diagram view of a portion of the process 700 of operation for automatic volume restoration using interrupts is shown in accordance with various embodiments. Collectively, the interrupt detection, automatic setting application, and restoration operations may be referred to as the volume interrupt process 700. The process 700 receives an interrupt in start block 710. In an embodiment using multiple interrupts, the process 700 determines the type of interrupt in block 720 and determines whether there are any user-defined settings related to the detected interrupt in query block 730. Factory-preset volume settings are retrieved by the process 700 in block 740. Alternatively, user-defined volume settings may be retrieved by the process 700 in block 750. In addition to automatic volume setting information, an interrupt type in various configurations may also provide priority information and/or connection type information to the communication node. Once the settings have been retrieved and the priority verified, the process 700 may interrupt the current stream in block 760.

In one embodiment, the current stream is a music stream and is stopped until the interrupt is handled. Other configurations merely stop transmitting the stream to the output device until after the interrupt has been handled. The volume for the signal interrupting the music stream is set in block 770 by the process 700 according to the retrieved interrupt setting. Accordingly, depending on the interrupt type, connection type, and duration of the expected interruption, the manner of the interruption of the stream may be modified. For example, in one configuration the pending stream may be buffered and/or delayed to start at the last point in the stream prior to the interruption.

Upon completion of the volume adjustment and playback of the stream associated with the interrupt, the process 700 restores the original stream to a playback status in block 780, including the restoration of the original volume before the interrupt occurred, and returns to normal playback mode in termination block 790. Clearly, the interrupt option allows the process 700 to handle the steps of cutting into a playing stream and restoring the stream in different ways. For example in a music stream embodiment with long interrupts, where the length of the stream associated with the interrupt exceeds the available buffer size, may simply restart the stream of music at the beginning upon return from the interrupt. Alternatively, the longer interrupt may continue to stream the music in the background and simply start later in the stream.

Alternatively, in other embodiments, a generic interrupt may be used to initiate the automatic volume restoration process for a detected connection type. Under the generic interrupt configuration, connection type discovery as previously outlined may be used to establish volume settings. In this case receipt of an interrupt may, or may not, provide the process with specific information regarding the priority and size of the stream associated with the interrupt. Thus, the system could take a default approach similar to those previously discussed to handle each new interrupt.

The above specification, examples and data provide a complete description of the manufacture and use of the composition of the invention. Although specific embodiments have been illustrated and described herein, it will be appreciated by those of ordinary skill in the art and others, that a wide variety of alternate and/or equivalent implementations may be substituted for the specific embodiment shown in the description without departing from the spirit and scope of the present invention. This application is intended to cover any adaptations or variations of the embodiments discussed herein. Therefore, it is manifested and intended that the invention be limited only by the claims and the equivalence thereof.

What is claimed is:

1. A method for restoring volume at a communication node in a distributed communication system, comprising:
receiving a transmission for a communication node, the transmission having a connection type;
retrieving volume control configuration information based on the received transmission connection type; and
broadcasting the transmission in accordance with the retrieved volume control configuration information for the received connection type.

2. The method of claim 1, wherein the receiving comprises receiving a stream for transmission at a communication node from a remote communication node.

3. The method of claim 1, wherein the receiving comprises receiving a request by a first communication node for a transmission and subsequently retrieving the requested transmission from a storage medium coupled to a second communication node.

4. The method of claim 3, wherein the first communication node and the second communication node are the same communication node.

5. The method of claim 4, wherein the first communication node and/or the second communication node are part of a remote communication node.

6. The method of claim 1, wherein the retrieving comprises retrieving from a storage medium.

7. The method of claim 6, wherein the storage medium is associated with a remote communication node.

8. The method of claim 6, wherein the retrieving the volume control configuration information further includes retrieving local volume control settings from the storage medium for a communication node configured to broadcast the transmission.

9. The method of claim 8, wherein the local volume control settings include user-defined volume settings assigned in accordance with environmental characteristics of the communication node to broadcast the transmission.

10. The method of claim 1, wherein the retrieving the volume control configuration information comprises determining whether automatic configuration information is available for the received transmission connection type.

11. The method of claim 1, wherein the retrieving the volume control configuration information comprises determining whether default configuration and/or user-defined configuration information is available for the received transmission connection type.

12. The method of claim 1, further comprising configuring a communication node to broadcast the transmission in accordance with the retrieved volume control configuration information.

13. The method of claim 1, wherein the broadcasting comprises producing an audible signal using an output device of a communication node configured in accordance with the retrieved volume control configuration information.

14. A communication node comprising:
an audio output device;
at least one communication interface; and
a communication module coupled to the at least one communication interface and adapted to perform at least one of:
(a) generate a first transmission request including a first desired connection type and transmit the first transmission request via the at least one communication interface among other nodes of a first distributed communication network to facilitate selective data communication between nodes;
(b) receive a second transmission request, having a second desired connection type, from other nodes of a second distributed communication network, via the at least one communication interface and determine whether automatic volume configuration information for the received second desired connection type is available; and
(c) automatically adapt volume settings of the audio output device based on a third desired connection type communication.

15. The node of claim 14, wherein the communication node is adapted to perform at least (a) and (b), and
the first transmission request and the second transmission request are the same transmission request;
the first desired connection type and the second desired connection type are a single desired connection type; and
the first distributed communication network and the second distributed communication network are a single distributed communication network.

16. The node of claim 14, wherein the communication node is adapted to perform at least (a) and (c), and the first desired connection type and the third desired connection type are a single desired connection type.

17. The node of claim 14, wherein the communication node is adapted to perform at least (b) and (c), and the first desired connection type and the third desired connection type are a single desired connection type.

18. The node of claim 14, wherein the communication node is adapted to perform (a), (b), and (c), and
the first transmission request and the second transmission request may be a single transmission request,
the first desired connection type and the second desired connection type and the third desired type are a single desired connection type, and
the first distributed communication network and the second distributed communication network are a single distributed communication network.

19. A communication arrangement enabling automatic volume adjustment in communication nodes of a distributed communication network, comprising:
a first communication node having a variable volume audio output device with logic configured to enable automatic adjustment of volume and at least one input device;
a second communication node having a variable volume audio output device with logic configured to enable automatic adjustment of volume and at least one input device,
wherein each of the first and the second communication nodes includes logic configured to enable the communication nodes to communicate with each other in accordance with a communication protocol that provides for each communication node to receive each communication initiated by the other communication node, independent of whether a communication node is an intended recipient of a communication; and
a transmission segment configured in accordance with a connection type configured to couple the first communication node and the second communication node, each connection type having a user-defined volume setting and/or a default volume setting.

20. The communication arrangement of claim 19, wherein the connection type is an audio communication connection type selected from the group consisting of an intercom connection type, a music connection type, a door-chime connection type, a video connection type, a data connection type, and a multimedia connection type.
